(19) United States
(12) Patent Application Publication
(10) Pub. No.: US 2026/0338832 A1
(43) Pub. Date: Oct. 29, 2026

(54) AUTOMATICALLY CONFIGURING A PATTERN TRIGGER FOR A PRBS SIGNAL USING MACHINE LEARNING IN A TEST AND MEASUREMENT INSTRUMENT

(71) Applicant: Tektronix, Inc., Beaverton, OR (US)

(72) Inventor: P E Ramesh, Banaglore (IN)

(21) Appl. No.: 19/547,612

(22) Filed: Feb. 23, 2026

(30) Foreign Application Priority Data
Feb. 21, 2025 (IN) 202521015152

(51) Int. Cl. G01R 13/02; G01R 23/18; G01R 31/3183; G01R 31/319; G06V 10/764

(52) U.S. Cl. CPC G01R 13/029; G01R 13/0209; G01R 13/0254; G01R 23/18; G01R 31/31919; G06V 10/764; G01R 31/318385

(57) ABSTRACT

In some aspects, a test and measurement instrument may include acquiring at least a portion of a repeating pattern signal from a DUT as an acquired waveform. Also, the instrument may include preprocessing the acquired waveform to generate a waveform image. Furthermore, the instrument may include sending the waveform image to a trained machine learning network. In addition, the instrument may include receiving a prediction of a PRBS signal type from the trained machine learning network based on the waveform image. Moreover, the instrument may include automatically configuring trigger circuitry to cause the instrument to trigger on the predicted PRBS signal type.

### CROSS-REFERENCE TO RELATED APPLICATION

This application claims priority from India Provisional Pat. App. No. 202521015152, filed Feb. 21, 2025, which is hereby incorporated by reference in its entirety.

### TECHNICAL FIELD

This disclosure relates to test and measurement instruments, including oscilloscopes, and more particularly to automatically setting a pattern trigger for a pseudo-random bit sequence (PRBS) signal.

### BACKGROUND

In general, signal integrity is paramount in a high-speed serial interface. Time domain simulation is the preferred to design any serial interface. During the design, the serial data is being simulated with all possible combinations randomly using a pseudo-random bit sequence (PRBS) signal, as the serial data. It is ensured that these data being simulated as real signal and decoded at the receiver to measure the Bit error testing for any serial interface.

However, PRBS signals can be generated using different algorithms. The most used technique is the Linear Feedback Shift Register (LFSR). LFSR-based generators utilize shift registers and feedback connections to produce PRBS signals. PRBS signals find extensive applications in digital communication systems. PRBS signals are used for channel characterization, testing signal integrity, equalization, and error detection and correction algorithms. PRBS-based test patterns help assess the performance of communication links under different conditions.

Quite often when the PRBS signal is sent, the type of the PRBS which is based on polynomial is not known. Polynomial defines the repetition rate based on its PRBS type which may be PRBS 7, 9, 11, 13, 15 etc.

This defines the repetition rate of the sequence. By finding the PRBS sequence, with serial trigger on the scope, one can trigger on the sequence and debug the signal integrity and can also verify the pattern if the receiver fails or Bit error rate is high. The conventional way of finding the bit sequence is to convert the incoming signal into bit pattern and compare the bit pattern with pre-defined bit pattern then arrive at it. However, this method is slow, cumbersome, and prone to error. Therefore, there is a need for an improved way of identifying a particular PRBS signal and triggering on the signal.

Whereas machine learning based detection will detect by taking the signal as input and classify the PRBS type. With PRBS type one can set the trigger internally and debug the signal.

Thus, there is a need for a solution for training the ML model such that it can concretely classify the PRBS type.

### BRIEF DESCRIPTION OF THE DRAWINGS

FIG. 1 is a confusion matrix illustrating performance of a trained machine learning network, according to an exemplary implementation of the present disclosure.

FIG. 2 is a confusion matrix illustrating performance of a trained machine learning network, according to an exemplary implementation of the present disclosure.

FIG. 3 illustrates example spectrum images for different PRBS signals, according to an exemplary implementation of the present disclosure.

FIG. 4 is a block diagram of a test and measurement instrument, according to an exemplary implementation of the present disclosure.

FIG. 5 is a flowchart of a method, according to an exemplary implementation of the present disclosure.

### DETAILED DESCRIPTION

The various embodiments of the present disclosure describe techniques for Machine Learning-Based Spectral Analysis for PRBS Detection and Auto-Triggering in High-Speed Serial Communication compared to conventional edge-based signal detection.

In the following description, for the purpose of explanation, specific details are set forth in order to provide an understanding of the present disclosure. It will be apparent, however, to one skilled in the art that the present disclosure may be practiced without these details. One skilled in art will recognize that embodiments of the present disclosure, some of which are described below, may be incorporated into a number of systems.

However, the systems and methods are not limited to the specific embodiments described herein. Further, structures and devices shown in the figures are illustrative of exemplary embodiments of the present disclosure and are meant to avoid obscuring of the present disclosure.

It should be noted that the description merely illustrates the principles of the present invention. It will thus be appreciated that those skilled in the art will be able to devise various arrangements that, although not explicitly described herein, embody the principles of the present invention. Furthermore, all examples recited herein are principally intended expressly to be only for explanatory purposes to help the reader in understanding the principles of the invention and the concepts contributed by the inventor to furthering the art and are to be construed as being without limitation to such specifically recited examples and conditions. Moreover, all statements herein reciting principles, aspects, and embodiments of the invention, as well as specific examples thereof, are intended to encompass equivalents thereof.

According to the present disclosure the proposed model is two step approach: training and runtime.

Regarding training, there is no existing training set available on finding out the features that need to be extracted for the ML model. Training the ML model such that it can concretely classify the PRBS type. First, ML models based on representation learning are used to learn relevant features from the waveform. This corresponds to projecting the input data onto a new latent representation, referred to as feature space. Then training the CNN using the feature space for classifying the PRBS in the new feature space.

The methodology generally consists of two main phases:
1) Data preprocessing
2) Training ML model for the feature extraction and classification.

The phases are described below:

Data Preprocessing: First, the signals under study (the raw input data) may go through a series of preprocessing steps to be used as input for a ML model. Since the raw data is a continuous time-series signal in time series signal represent time and amplitude on X and Y axis, This can be split into sub-sequences using a sliding window approach. The sliding window overlap can be as slow as one sample interval or as high one unit interval.

Feature Extraction: There are two types of feature space, one is Time series and another is Spectrum image.

The time series involves creating the waveform with X as Time and Y as signal value, then one needs to train the time series that can start from anywhere randomly. Embodiments of the disclosure using time series feature space did not perform well. Training and classifying the PRBS worked only for the trained set of Data sequence, when new waveform sequence is given, this training and classification failed to determine the correct PRBS sequence even though it is trained.

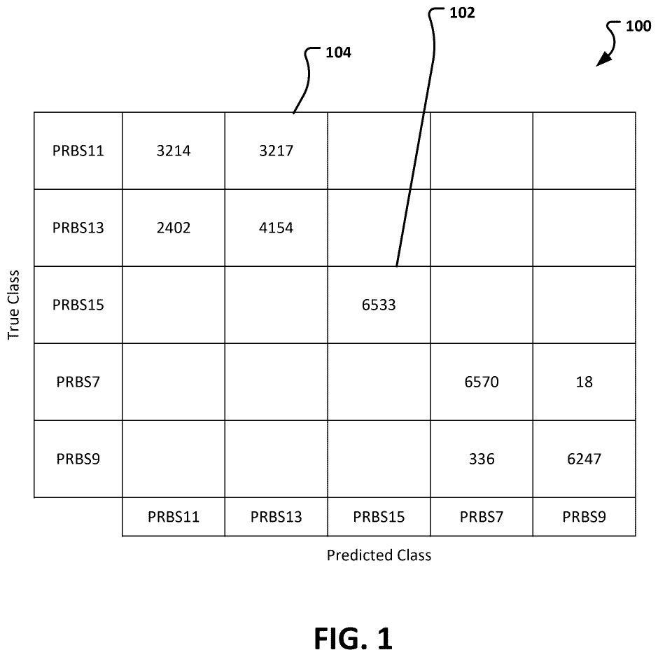

FIG. 1 illustrates the performance of the network trained with time series input according to an exemplary implementation of the present disclosure. Here the network with time series input is trained with a classification label attached. The confusion matrix 100 did not give favorable results for the trained waveforms using time series data. This is because for the given input cycle of Max PRBS length, there is possibility of a similar time series for the given PRBS waveforms. As shown in cell 102 of the confusion matrix 100, PRBS15 is a unique sequence, and the trained network is able to identify it well, without mistakes in classification. However, other PRBS might be the similar sequence overlapping with other PRBS types. The trained network was not able to consistently classify the other PRBS signals, besides PRBS15, as shown in the “off-diagonal” cells, such as 104 that show a miscategorization of PRBS type.

Other embodiments of the disclosure using spectrum image feature space worked well. In these embodiments, the PRBS signal in time domain is converted to frequency domain and the frequency domain image is used as feature for training the Network. In an exemplary implementation of the present disclosure, “Googlenet” available in MATLAB as a pre-trained network for various images, was used for training the spectrum image.

According to the exemplary implementation of the present disclosure, the Google Net has been trained on over a million images and can classify images into 1000 object categories (such as keyboard, coffee mug, pencil, and many animals). The network has learned rich feature representations for a wide range of images. The network takes an image as input and then outputs a label for the object in the image together with the probability for each of the object categories.

Google Net is a convolutional neural network that is 22 layers deep. One can load a pretrained version of the network trained on either the ImageNet or Places365 data sets. The network trained on ImageNet classifies images into 1000 object categories, such as keyboard, mouse, pencil, and many animals. The network trained on Places365 is similar to the network trained on ImageNet, but classifies images into 365 different place categories, such as field, park, runway, and lobby. These networks have learned different feature representations for a wide range of images.

Therefore, training the pre-trained image network needs less training data sets for the improved prediction.

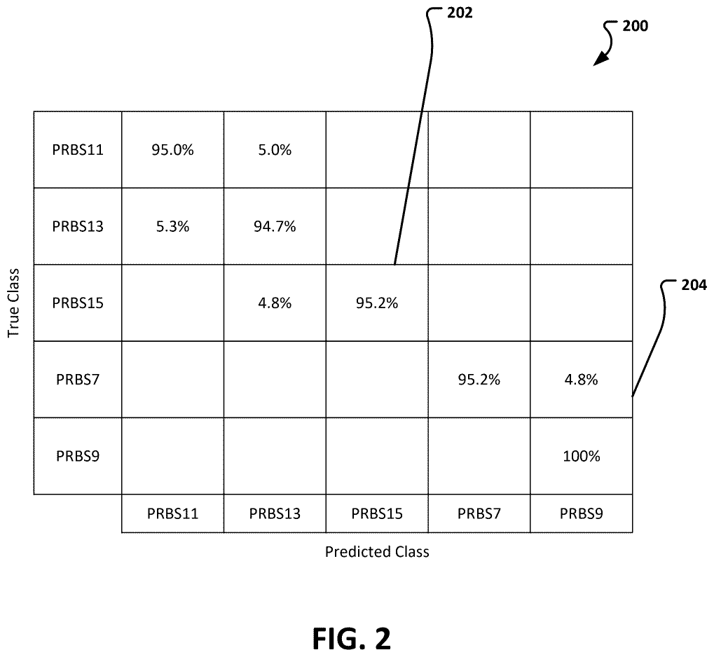

FIG. 2 illustrates the performance of the network trained with spectrum image input according to an exemplary implementation of the present disclosure. Here the network with spectrum input is trained with a classification label attached. As shown in the confusion matrix 200 in FIG. 2, the network trained with spectrum image input produced a classification accuracy of around 95% for all PRBS types, such as the 95.2% accuracy for PRBS15, shown in cell 202. There are still some misclassifications, such as the 4.8% of PRBS7 being misidentified as PRBS9 as shown in cell 204, but these are adequate results. The pre-trained image networks used to produce the results shown in FIG. 2 were trained with different types of PRBS with more than 400 images. Accuracy could be improved even further with additional training cycles.

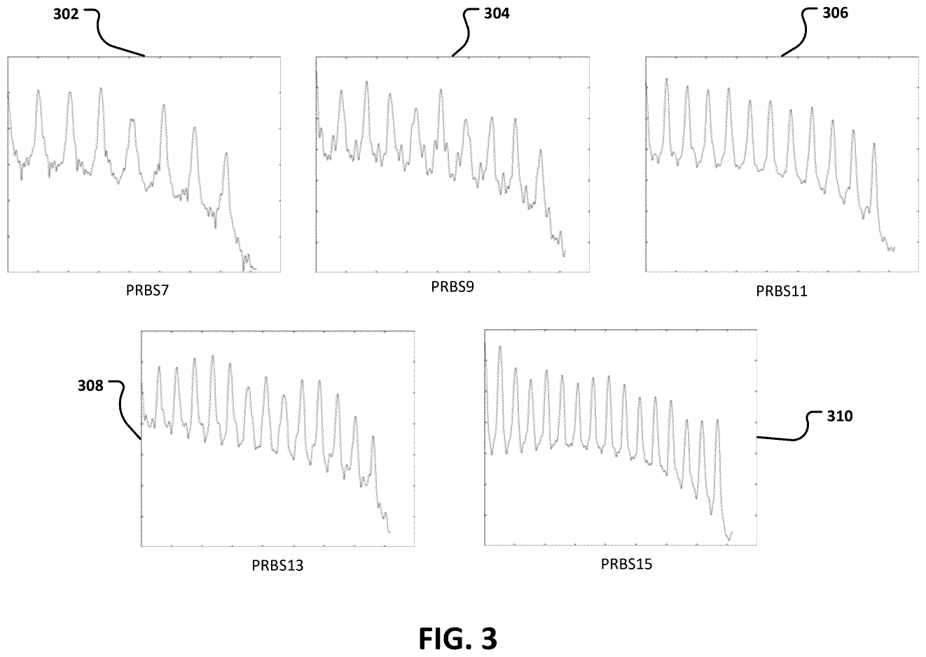

FIG. 3 shows examples of the spectrum images for different types of PRBS signals. Image 302 is an example spectrum image of a PRBS7 signal. Image 304 is an example spectrum image of a PRBS9 signal. Image 306 is an example spectrum image of a PRBS11 signal. Image 308 is an example spectrum image of a PRBS13 signal. Image 310 is an example spectrum image of a PRBS15 signal. These, and similar, images are used as inputs for the training, as well as during runtime, as described below.

Serial Pattern Auto finding and Triggering: In High-speed serial standards, PRBS waveform as test signal is used. These test signals are used either to perform the Signal integrity and compliance at the transmitter (TX) or the bit error rate (BER) at the receiver. There is no conventional mechanism to verify the PRBS Type of the signal in the scope and to set the trigger automatically for particular PRBS type for stable triggering. The stable triggering helps to debug the PRBS type and arrive at to verify their LFSR status and implementation.

The alternate way is to analyze the waveform, convert into bit sequence, then compare the sequence to specific PRBS sequence then arrive at the PRBS type and this involves series of steps before one can arrive at PRBS type.

Regarding runtime, according to the present disclosure, the acquired waveform is passed on and converted to image using preprocessing, ML is used to classify the PRBS type, and once the PRBS type is known the trigger can be set automatically for this type and the scope can be triggered using serial pattern trigger to get the stable signal on the scope. This not only verifies the PRBS type but also creates the stable display for the incoming signal.

The solution of the present disclosure is developed to verify the concept of finding the PRBS type of the acquired signal. The waveform is received from the oscilloscope, preprocessed to spectral image, and then passed on to the trained network for the classification. The output will be verdict in types and verdict can be used for setting up the pre-defined trigger pattern for the respective PRBS to get the stable trigger on the signal.

According to the present disclosure the sensitivity of the ML based method is based on the unique Spectral analysis where minimal signal strength is required whereas in conventional way, one needs the signal strength that should overcome the Signal levels needed for edge finding and hysteresis for concrete analysis.

In an exemplary implementation of the present disclosure, the signal amplitude can be as low as 0.5 division which can be decoded using this method whereas conventional method needs minimum of 1 division of the signal.

In another exemplary implementation of the present disclosure, the signal can have impairments such as ISI, cable effect and noise, still the spectrum image differentiates it whereas conventional method based on the edge finding and these artifacts severely limit finding the correct patterns. Besides, conventional method involves acquiring signal for one full compete repetition of pattern whereas in frequency domain partial acquisition length is good enough. The auto triggering using serial trigger after finding the pattern type is unique feature on the scope to lock on to the incoming sequence of the signal.

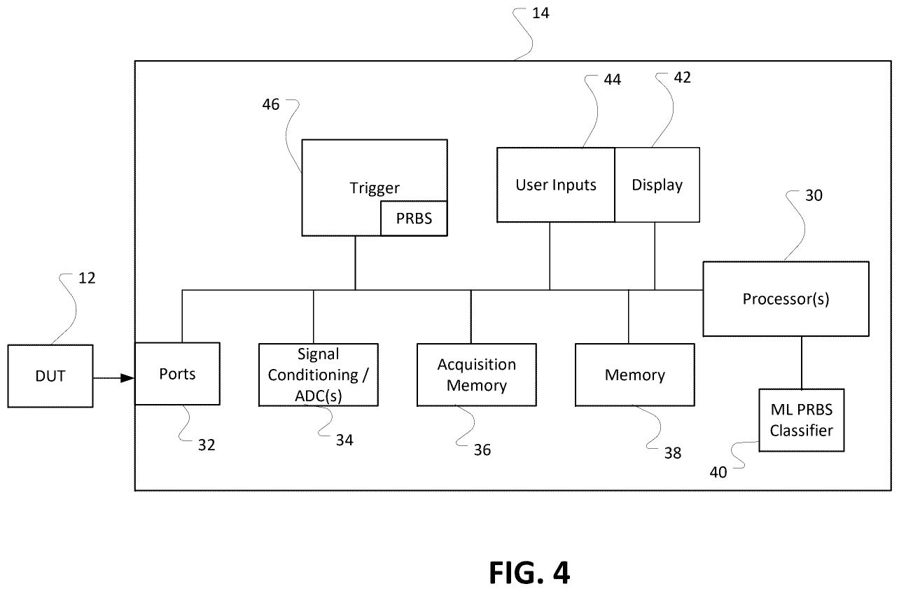

FIG. 4 shows an embodiment of a test and measurement instrument, according to embodiments of this disclosure. The test and measurement instrument 14 may include several components, and the ones described here are not intended to be exhaustive.

The test and measurement instrument 14 may include one or more input ports 32 that are structured to receive a signal from a DUT 12. As discussed above, in some embodiments, the DUT may be a transmitter, and the instrument will receive the transmitted signal, in some cases after transmission through a communication channel which may introduce distortions to the transmitted signal. In other embodiments, the DUT may be a receiver. The instrument may include one or more analog-to-digital converters (ADCs) 34 that convert the received analog signal into digitized samples. The instrument will include at least one memory, such as an acquisition memory 36 that stores the acquired digitized samples and the waveforms used in training, etc. Memory 38 that may be combined with memory 36 and may store the code to be executed by the processor 30, as well as store user settings, etc. The user inputs 44 may include knobs, buttons, and other controls. The display 42 displays the waveforms and resulting measurements to the user. The display may optionally incorporate user controls if the display 42 is a touch screen display.

According to some embodiments, the instrument 14 is an oscilloscope. In these embodiments, the display may comprise a classic oscilloscope graph display showing 10 major horizontal divisions and 8 major vertical divisions. The vertical scale control (e.g. Volts/div) of the input to which the DUT signal is connected can be adjusted to increase or decrease the displayed amplitude of the DUT signal. Typically, for optimal use of the dynamic range of the acquisition circuitry, and better measurement results, a user would adjust the vertical scale so that the input signal amplitude occupies the majority of the vertical divisions on the display. However, as mentioned above, embodiments of this disclosure are still able to properly categorize a small amplitude input PRBS signal type without needing to adjust the vertical scale. This can be very useful in real world environments where the signal amplitude can be severely impacted by signal impairments.

The instrument may include trigger circuitry 46. The trigger circuitry may operate on the analog input signal, or on the acquired digital samples. The trigger circuitry operates to trigger the instrument on a defined event or feature of the input signal, determining which portion of the input signal gets stored in the memory, and causing the display of the input signal to be stable. The trigger circuitry may include serial pattern trigger circuitry, and more specifically, PRBS trigger circuitry, which allows the instrument to trigger on a known type of PRBS signal.

The test and measurement instrument 14 may include one or more processors 30. The one or more processors are configured to execute code that will cause the one or more processors to perform the processes discussed herein. The instrument may include a PRBS classifier machine learning network 40. Although depicted as being a separate component of instrument 14, the machine learning network 40 may, in some embodiments, be implemented in the one or more processors 30 and memory 38. Additionally, in some embodiments, the machine learning network 40 may be implemented in a computing system that is separate from the instrument 14, and would be communicated with by the one or more processors 30 through a communications port, e.g. over a communication network. The various processing tasks described herein may be distributed between the one or more processors in the instrument and the machine learning network.

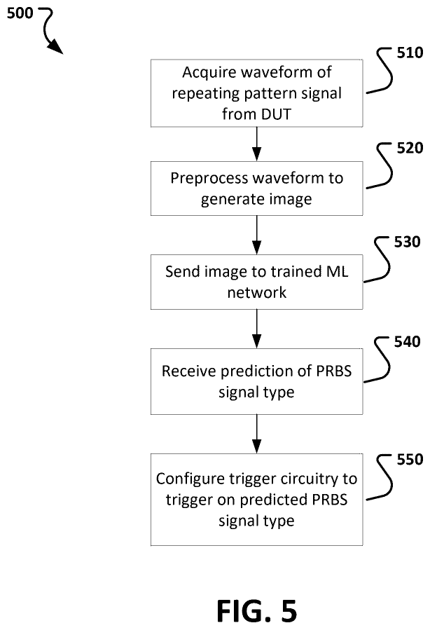

FIG. 5 is a flowchart of a method 500 of triggering a test and measurement instrument, according to embodiments of this disclosure. At operation 510, at least a portion of a repeating pattern signal from a DUT is acquired as an acquired waveform. At operation 520, the acquired waveform is preprocessed to generate a waveform image. In some embodiments, preprocessing the acquired waveform includes converting a time domain waveform to a frequency domain waveform, using, for example a Fast Fourier Transform, Discrete Fourier Transform, etc., and generating a spectral image as the waveform image. At operation 530, the waveform image, which may be a spectral image is sent to a trained machine learning network. At operation 540, the machine learning network provides a predicted PRBS signal type based on the waveform image. At operation 550, the method automatically configures trigger circuitry in the instrument to cause the instrument to trigger on the predicted PRBS signal type.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

Additionally, this written description makes reference to particular features. It is to be understood that the disclosure in this specification includes all possible combinations of those particular features. For example, where a particular feature is disclosed in the context of a particular aspect, that feature can also be used, to the extent possible, in the context of other aspects.

Also, when reference is made in this application to a method having two or more defined steps or operations, the defined steps or operations can be carried out in any order or simultaneously, unless the context excludes those possibilities.

Although specific aspects of the disclosure have been illustrated and described for purposes of illustration, it will be understood that various modifications may be made without departing from the spirit and scope of the disclosure. Accordingly, the disclosure should not be limited except as by the appended claims.

What is claimed is:

1. A test and measurement instrument comprising:
an input for receiving a repeating pattern signal from a device under test (DUT); and
one or more processors configured to execute code that causes the one or more processors to:
acquire at least a portion of the signal from the DUT as an acquired waveform;
preprocess the acquired waveform to generate a waveform image;
send the waveform image to a trained machine learning network; and
receive a prediction of a pseudo-random bit sequence (PRBS) signal type from the trained machine learning network based on the waveform image.

2. The test and measurement instrument of claim 1, wherein preprocessing the acquired waveform comprises converting time domain waveform data to frequency domain waveform data.

3. The test and measurement instrument of claim 2, wherein the waveform image comprises a spectrum image.

4. The test and measurement instrument of claim 1, further comprising serial data pattern trigger circuitry.

5. The test and measurement instrument of claim 4, wherein the one or more processors are further configured to execute code to cause the one or more processors to automatically configure the serial data pattern trigger circuitry to cause the instrument to trigger on the predicted PRBS signal type.

6. The test and measurement instrument of claim 1, wherein the predicted PRBS signal type is one of PRBS7, PRBS9, PRBS11, PRBS13, and PRBS15.

7. The test and measurement instrument of claim 1, wherein acquiring at least a portion of the signal from the DUT comprises acquiring less than a full repetition of the repeating pattern signal.

8. The test and measurement instrument of claim 1 wherein the repeating pattern signal from the DUT is a particular type of PRBS signal, and the particular type of PRBS signal is unknown to a user of the test and measurement instrument prior to acquiring the signal.

9. The test and measurement instrument of claim 1, wherein the signal from the DUT includes one or more signal impairments.

10. The test and measurement instrument of claim 1, wherein the instrument is an oscilloscope.

11. The test and measurement instrument of claim 10, further comprising a display, and wherein an amplitude of the signal from the DUT occupies between 0.5 to 1 divisions of the display.

12. A method of triggering a test and measurement instrument, comprising:
acquiring at least a portion of a repeating pattern signal from a DUT as an acquired waveform;
preprocessing the acquired waveform to generate a waveform image;
sending the waveform image to a trained machine learning network;
receiving a prediction of a PRBS signal type from the trained machine learning network based on the waveform image; and
automatically configuring trigger circuitry to cause the instrument to trigger on the predicted PRBS signal type.

13. The method of claim 12, wherein preprocessing the acquired waveform comprises converting time domain waveform data to frequency domain waveform data to generate a spectrum image as the waveform image.

14. The method of claim 12, wherein the predicted PRBS signal type is one of PRBS7, PRBS9, PRBS11, PRBS13, and PRBS15.

15. The method of claim 12, wherein acquiring at least a portion of the repeating pattern signal from the DUT comprises acquiring less than a full repetition of the repeating pattern signal.

16. The method of claim 12, wherein the signal from the DUT includes one or more signal impairments.

17. The method of claim 12, wherein the trained machine learning network comprises a pretrained convolutional neural network (CNN).

18. The method of claim 17, wherein the pretrained convolutional neural network comprises a GoogleNet CNN.

19. The method of claim 17, further comprising augmenting the training of the pretrained CNN using additional training data sets comprising waveform images of PRBS signals and corresponding PRBS signal type labels.

20. The method of claim 19, wherein the waveform images of PRBS signals comprise spectral images of PRBS signals.
